(19) United States
(12) Patent Application Publication
(10) Pub. No.: US 2006/0065635 A1
(43) Pub. Date: Mar. 30, 2006

(54) Deposition chamber surface enhancement and resulting deposition chambers

(76) Inventors: Garo J. Derderian, Boise, ID (US); Gurtej S. Sandhu, Boise, ID (US); Ross S. Dando, Nampa, ID (US); Craig M. Carpenter, Boise, ID (US); Philip H. Campbell, Meridian, ID (US)

Correspondence Address: TRASK BRITT, P.O. BOX 2550, SALT LAKE CITY, UT, 84110, US

(21) Appl. No.: 11/271,673

(22) Filed: Nov. 9, 2005

Related U.S. Application Data
(62) Division of application No. 10/340,322, filed on Jan. 9, 2003.

(51) Int. Cl. C23C 16/52; C03C 15/00

(52) U.S. Cl. 216/89; 427/8

(57) ABSTRACT

Methods for passivating exposed surfaces within an apparatus for depositing thin films on a substrate are disclosed. Interior surfaces of a deposition chamber and conduits in communication therewith are passivated to prevent reactants used in a deposition process and reaction products from adsorbing or chemisorbing to the interior surfaces. The surfaces may be passivated for this purpose by surface treatments, lining, temperature regulation, or combinations thereof. A method for determining a temperature or temperature range at which to maintain a surface to minimize accumulation of reactants and reaction products is also disclosed. A deposition apparatus with passivated surfaces within the deposition chamber and gas flow paths is also disclosed.

This application is a divisional of application Ser. No. 10/340,322, filed Jan. 9, 2003, pending.

### BACKGROUND OF THE INVENTION

1. Field of the Invention

The present invention relates generally to vapor and gas delivery systems. More particularly, the present invention relates to deposition chambers used for depositing thin films in the semiconductor industry.

2. State of the Art

As the size of semiconductor devices in the semiconductor industry continues to decrease, improved systems and methods for producing thin films on the devices must be developed. Conventional technologies used for producing thin films include chemical vapor deposition (CVD) and plasma-enhanced chemical vapor deposition (PECVD).

CVD methods are widely used in the semiconductor industry for depositing thin films. In a conventional CVD process, the thin films and layers are deposited on a substrate to a desired thickness in a sealed deposition chamber, which may also be termed a “reaction chamber.” To deposit the thin film, the substrate is placed in a deposition chamber, the chamber is sealed, the substrate is heated, and a mixture of gases is introduced into the chamber. A chemical reaction in the chamber proceeds to deposit the desired thin film or layer of material on the substrate, as known to those of ordinary skill in the art. Although CVD has proven to be an efficient method of depositing thin films, the demand for smaller semiconductor devices requires even higher quality, thinner films which conventional CVD processes are unable to consistently produce.

It has been recognized by the inventors herein that conventional CVD chambers are not particularly conducive to conversion to atomic layer deposition (ALD) methods. Accordingly, research and development has been ongoing to provide improved deposition chambers more suitable to produce the extremely thin films of ALD methods. ALD processes exhibit advantages over CVD processes, such as being able to deposit controlled-thickness films at lower temperatures than those used to deposit films by CVD processes. Also, ALD processes may be used to form much thinner films (i.e., films for gate oxides, cell dielectrics, or diffusion barriers) than those formed by CVD processes, on the order of one or a few atomic layers of the deposited material. Furthermore, ALD may be used to deposit a range of materials with greater uniformity and better coverage than films that have been formed by CVD processes. However, the chemical reactions used in the ALD processes result in more byproduct adduct accumulation on interior surfaces of the deposition chamber than the CVD processes. Also, the interior surfaces may act as sources to degrade ALD behavior. The byproduct accumulation causes particle contamination problems, wherein the accumulation within the chamber must be wet cleaned or scrubbed to remove the excess byproduct residue. Therefore, the deposition chambers used for traditional CVD methods are not suitable for ALD processes.

In ALD processes, the reactant gases comprising precursors to the material to be deposited are typically introduced into a reaction chamber one at a time, unlike CVD processes where two or more precursor reactant gases may be introduced into a reaction chamber at the same time and reacted to form a thin film. In the ALD process, a first reactant gas, or precursor, is introduced into the reaction chamber through a gas line or a distribution head such as a so-called “shower head” (due to its physical configuration) wherein a monolayer of the first reactant gas or vapor, such as water vapor, is adsorbed on the substrate surface through chemisorption. However, the interior surfaces of the deposition chamber may also be coated with the first reactant gas, e.g., water vapor. The water vapor is then evacuated from the reaction chamber and an inert gas may be used to purge, or pump, the water from the reaction chamber, wherein the inert purge gas does not adsorb onto the surface of the substrate or the reaction chamber. A second reactant gas or vapor is then introduced into the reaction chamber, where the water on the substrate surface and the second reactant gas react on the surface of the substrate, or deposition chamber if water has adhered to the interior surface, to produce a material layer having a thickness that may be measured as a number of atoms. In this manner, reactant gases are “pulsed” onto the surface of the substrate inside the deposition chamber in a sequential manner to form atomic layers of the desired material, one layer at a time.

However, since the reactant gases used in ALD processes are very reactive, when the reactant gases are exposed to each other anywhere in the chamber in addition to the surface of the substrate, the reactant gases will likely react and, thus, form particles or a film on any surface they contact by adhering, or “sticking,” to the surface by physical adsorption, chemisorption or condensation. Thus, the reaction chamber may have residual reactant gases deposited on the various interior surfaces of the chamber, which may result in unwanted chemical reactions. The unwanted chemical reactions may result in a decreased efficiency of the deposition process, corrosion of the interior surfaces of the deposition chamber (i.e., gas lines, shower head, chamber walls, etc.) and a shortened life of the ALD chamber (i.e., two to five years). In addition to making the deposition process inefficient, the residual reactants may result in impure thin films being formed on the substrate.

Another problem with ALD is the slowness of the process caused by the step-wise fashion in which the process must be repeatedly conducted, which results in a time-intensive process. Since the ALD processes are, by themselves, time-intensive, any additional time that is lost due to cleaning incidentally deposited reactants from the reaction chamber or the loss of components in the ALD deposition chamber makes the ALD process less efficient due to cleaning downtime or replacement of the corroded components used for the ALD deposition process.

Another problem with both ALD and CVD-type deposition processes is deposition chamber component corrosion. For instance, a plasma enhanced chemical vapor deposition (PECVD) process that deposits TiCl₄ titanium or an ALD process that deposits WNₓ using WF₆ and NH₃ as process gases are each corrosive to the surfaces of the chambers exposed to the reaction, wherein the corrosion may shorten the life of the chamber. Although conventional anodization of aluminum has been used on the interior metal surfaces of deposition chamber components used for traditional CVD processes with some limited success, the result has proven to be inadequate.

Therefore, it would be desirable to provide a deposition chamber fabricated to minimize the incidental deposition of reactants by physical or chemisorption and to reduce consequential chamber contamination and component corrosion, thus enabling the desired deposition process to take place repeatedly over extended periods of time while maximizing chamber component life and minimizing the requirement for cleaning and other maintenance operations.

### BRIEF SUMMARY OF THE INVENTION

The present invention includes a method of producing a deposition apparatus, which includes a reaction, or deposition, chamber with substantially nonreactive, or passivated, component surfaces exposed to process reactants. The substantially nonreactive surfaces are designed such that the reactive gases used in the deposition process are unable to adhere to the surfaces of the reaction chamber in any substantial quantities and, thus, such that the nonreactive surfaces substantially prevent the incidental buildup of material layers or contaminants (and the potential for process contamination and component corrosion) on the surfaces of the reaction chamber or any other portion of the deposition apparatus. The present invention also includes a deposition apparatus with nonreactive component surfaces, wherein the component surfaces that may be exposed to reactant gases are passivated to produce a very hard, low-friction, nonstick surface to which reactant gases used in the deposition process will not substantially adhere.

The present invention also includes a deposition apparatus, also referred to herein as “deposition chamber,” used to produce thin films on substrates and to methods of fabricating the deposition chambers. In several embodiments, surfaces of the deposition chamber are passivated using one or more surface treatments to prevent any reactant gases used in the deposition process from substantially adhering to the surfaces of the deposition chamber.

In another embodiment of the present invention, a deposition chamber includes use of temperature regulation of interior surfaces of deposition chamber components such that the reactant gases used in a deposition process are substantially unable to adhere to the surfaces of the deposition chamber. Such surface temperature regulation may be effected without substantially increasing a temperature within the reaction chamber and, thus, without substantially interfering with an ongoing deposition process.

The present invention also includes a method of determining an optimized temperature or temperature range for one or more of the interior surfaces of a deposition chamber located within the deposition chamber to minimize adsorption and chemisorption of reactants to a surface thereof. The method may be based upon previously determined amounts of particular reactant materials that physically adsorb to, chemisorb to, or condense onto a surface of a deposition chamber at varying temperatures and under various process conditions. A temperature or temperature range over which a minimal amount of reactant adsorbs to the surface may be determined and surfaces maintained at such temperature or within such range during a deposition process.

### BRIEF DESCRIPTION OF THE SEVERAL VIEWS OF THE DRAWINGS

The nature of the present invention as well as other embodiments of the present invention may be more clearly understood by reference to the following detailed description of the invention, to the appended claims, and to the several drawings herein, wherein:

FIG. 1 is a partial cross-sectional schematic view of a deposition chamber according to the present invention;

FIG. 2 is a partial cross-sectional schematic view of the deposition chamber of FIG. 1 with the addition of a liner;

FIG. 3A is a graph depicting physical adherence of a reactant to a surface of a material;

FIG. 3B is a graph depicting chemisorption of a reactant to a surface of a material; and

FIG. 4 is a partial cross-sectional view of a deposition chamber with a heating element for preventing reactant materials from adhering to the surfaces of the deposition chamber.

### DETAILED DESCRIPTION OF THE INVENTION

Generally, the present invention includes a deposition apparatus for forming thin films of materials on various substrates, including, without limitation, semiconductor substrates, methods of fabricating such deposition apparatus, methods of reducing reactant gas and product adherence to surfaces of the apparatus, and methods for using the deposition apparatus. While the present invention is described in terms of certain specific, exemplary embodiments, the specific details of these embodiments are set forth in order to provide a thorough understanding of the present invention. It will be apparent, however, that the present invention may be practiced in various combinations of the specific, exemplary embodiments presented herein.

In describing the following embodiments, the terms “wafer” and “substrate” include any structure having an exposed surface upon which an insulator or insulative layer may be formed upon. The term “substrate” also includes semiconductor wafers and other bulk semiconductor substrates. The term “substrate” is further used to refer to semiconductor structures during processing, and may include other layers that have been fabricated thereupon. Both “wafer” and “substrate” include doped and undoped semiconductors, epitaxial semiconductor layers supported by a base semiconductor or insulator, as well as other semiconductor structures known to those of ordinary skill in the art.

In the description that follows, the term “deposition chamber” means and includes any deposition chamber used to deposit reactant materials as a film or layer onto a substrate, and components thereof. Known processes that use deposition chambers to deposit films or layers include, but are not limited to, atomic layer deposition (ALD) and chemical vapor deposition (CVD), including plasma enhanced chemical vapor deposition (PECVD), and rapid thermal chemical vapor deposition (RTCVD). As used herein, the terms “passivation” and “passivating” refer to the concept of making a surface harder or smoother, filling in gaps, voids, or vugs in a surface or otherwise imparting a surface with hard, low-friction, nonstick characteristics such that substances, such as reactant gases, will not substantially adhere thereto.

The present invention includes a deposition chamber suitable for forming a film or layer of material from gaseous or vaporized reactants on a surface of a substrate without substantially depositing the material onto surfaces of the deposition apparatus. The interior surfaces of the deposition chamber may be passivated such that the reactive gases and vapors are less likely to adhere to, or condense, on the surfaces of the deposition chamber. Thus, the deposition process performed in a deposition chamber of the present invention will be more efficient because there will be less contamination from residual reactants and fewer unwanted chemical reactions from the residual reactants. Furthermore, the deposition chamber described herein will have a longer life of use because the interior surfaces will be less likely to be corroded by the deposition of residual reactants or damaged by cleaning processes. The passivated surfaces described herein may be used, by way of example and not limitation, in deposition chambers for ALD, CVD, PECVD, RTCVD and other deposition processes known to those of ordinary skill in the art.

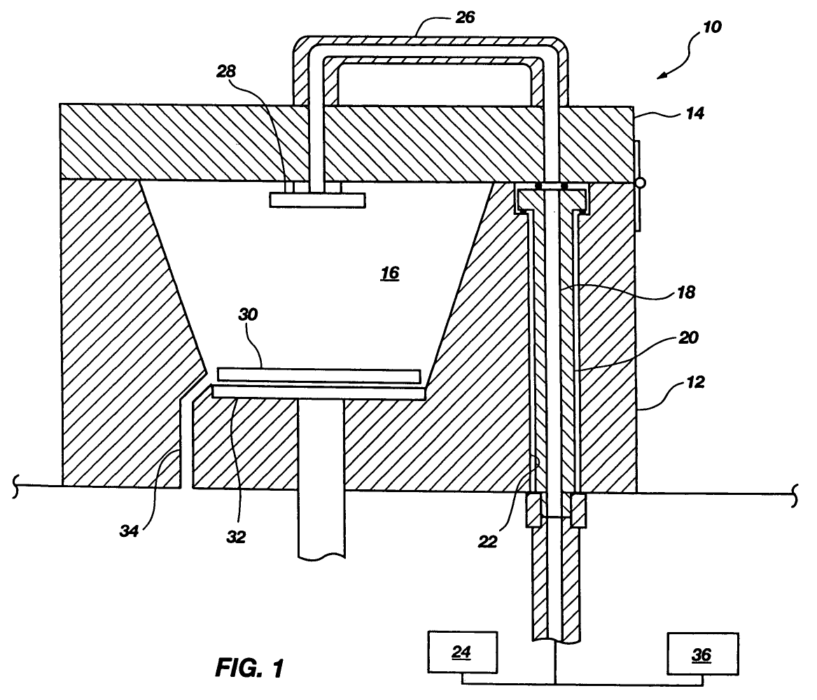

Referring now to FIG. 1, there is shown schematically an example of an exemplary deposition chamber with which teachings of the present invention may be used generally at 10. In the illustrated embodiment, the deposition chamber 10 is used for ALD, but it will appreciated by those of ordinary skill in the art that the deposition chamber 10 may be used for other deposition processes including, but not limited to, various types of CVD (e.g., PECVD, RTCVD, etc.). It will be further appreciated that the deposition chamber 10 is configured as a vacuum chamber, as is well known to those of ordinary skill in the art.

The exemplary deposition chamber 10 described herein is fabricated of a metal, as is well known to those of ordinary skill in the art. Metals that may be used to fabricate the deposition chamber 10 and the various components of the deposition chamber 10 include, but are not limited to, steel, stainless steel, nickel, aluminum, and alloys that include one or more of these materials. Alternatively, the deposition chamber 10 or components thereof may be constructed from ceramics or quartz.

As illustrated, the exemplary deposition chamber 10 includes a chamber body 12 and a chamber lid 14. The chamber body 12 encloses a chamber cavity 16, within which the deposition processes take place. The chamber lid 14 is removable from the chamber body 12 such that the chamber cavity 16 may be accessed for placement of a substrate 30 therein as well as for maintenance and cleaning. A gas delivery path 18 through the chamber body 12 includes a feedthrough device 20 disposed in a bore 22 in the chamber body 12. The feedthrough device 20 is also coupled with additional vapor plumbing 26 via the chamber lid 14 on the top of the deposition chamber 10. The gas delivery path 18 ultimately leads to a shower, or gas delivery, head 28 for discharging a purge gas into the chamber cavity 16 and for discharging reactant gases into the chamber cavity 16 for deposition of a material onto a substrate 30, such as a silicon wafer, which is positioned on a platform 32 that supports the substrate 30.

The gas delivery path 18 communicates with one or more associated reactant gas sources 24 associated with the deposition chamber 10. Although not depicted, when the gas delivery path 18 is connected to a plurality of reactant gas sources 24, the chamber cavity 16 may be provided with multiple species of reactant gases, concurrently or sequentially, as known in the art. The gas delivery path 18 is also connected to a purge gas delivery source 36, such that a purge gas may be introduced into the deposition chamber 10 through the gas delivery path 18.

The platform 32 may include heating mechanisms, as known in the art, for heating the substrate 30 during the deposition process, as is well known to those of ordinary skill in the art. Optionally, the deposition chamber 10 may include a plurality of platforms 32 for supporting a plurality of substrates 30 that has been placed inside the deposition chamber 10. An automated substrate handling apparatus may be provided in association with the platform 32 such that the process of positioning one or more substrates 30 within the deposition chamber 10 and removing the same subsequent to processing may be automated.

As illustrated, the deposition chamber 10 also includes an exhaust line 34 for exhausting gases from the deposition chamber 10 using a pump (not shown). It is apparent that although the illustrated deposition chamber 10 includes one gas delivery path 18 and one exhaust line 34, the deposition chamber 10 may include a plurality of gas delivery paths 18 and/or a plurality of exhaust lines 34 and not depart from the spirit of the present invention. For example, a separate gas delivery path 18 may be used to provide the purge gas from the purge gas delivery source 36.

In the illustrated embodiment, the gas delivery path 18 and exhaust line 34 comprise tubing fabricated from metal, but it will be appreciated that any type of conduit known to those of ordinary skill in the art for delivering and exhausting gases or vapors from a deposition chamber 10 are meant to be encompassed by the present invention. The deposition chamber 10 also includes various valves, flanges, couplings, seals, O-rings, gaskets, and other sealing devices (not shown) known to those of ordinary skill in the art for sealing the various paths and for allowing the various gases to enter and exit the deposition chamber 10 without leaking.

According to the present invention, surfaces of the various components of the deposition chamber 10 that are exposed to the gases or vapors may be passivated to prevent any gases, vapors, or reaction products from adhering to and corroding the exposed surfaces. If any surface or portion of a surface is not to be passivated, the area may be masked, as known to those of ordinary skill in the art, to prevent the passivation process from passivating the protected area. The passivation process makes the exposed surfaces nonreactive such that the reactant gases and purging gases used in the process will not physically adsorb, chemically adsorb, or adhere to the exposed surfaces in any manner. The passivation process may also make the exposed surfaces harder and smoother such that the deposition chamber 10 will be easier to clean if any materials do incidentally adhere to the passivated surface, making cleaning the deposition chamber 10 a quicker and more efficient process. Furthermore, the passivation process makes the surfaces more durable such that the deposition chamber 10 will resist wear from tools used for maintenance, abrasives used for cleaning, and also corrosion from byproduct build-up within the deposition chamber 10. The passivation treatment of the interior surfaces will provide a low-friction, nonstick, hard, passive surface with a low surface energy that will resist wear and corrosion, and will not peel or flake when stressed, as by thermal cycling of the deposition chamber 10. Further, the passivation processes described herein will lengthen the life of the deposition chamber 10.

In an embodiment of the present invention, the metal surfaces exposed to gases or vapors in the deposition chamber 10 may be passivated by adhering a coating material or materials to the surfaces. One material category that may be used to coat the exposed surfaces is a TEFLON® coating. TEFLON® coatings that may be suitable for use include, without limitation, polytetrafluoroethylene (PTFE), fluorinated ethylene propylene copolymer (FEP), perfluoroalkoxy (PFA), and a copolymer of ethylene and tetrafluoroethylene (ETFE). Adherence of TEFLON® brand coatings to metal surfaces of a deposition chamber may be enhanced in a manner known to those of ordinary skill in the art, such as by roughening the surface of the metal (e.g., sandblasting the metal surface), applying a primer such as primers designed using TEFLON® brand primer technology specific for use with TEFLON® brand coatings and offered by E.I. duPont de Nemours and company, of Wilmington, Del., to the roughened metal surface, and embedding the TEFLON® brand coating to mechanically bond within recesses formed in the primed metal surface. It will be further appreciated that TEFLON®-coated surfaces typically do not adsorb or bond to any materials, such that the various gases and vapors used in the deposition process will not adhere to the exposed TEFLON®-coated surfaces.

The use of some coating materials on the surfaces of a deposition chamber 10 of the present invention may not be compatible with certain reactants or purge gases and some coatings and coating materials may not be able to withstand certain elevated temperatures or other process conditions used in the deposition process for which a deposition chamber 10 is designed. Therefore, the selection of a coating or coatings to be used on the surfaces of a deposition chamber 10 will depend on both the reactants and the temperatures required for the deposition process for which that deposition chamber 10 will be used. For example, in the illustrated embodiment, the polymer used to coat a metal surface of deposition chamber 10 for use in an ALD process should be able to withstand temperatures commonly used for an ALD process, such as temperatures of about 150° C. to about 200° C. Alternatively, if the deposition chamber 10 described herein is to be used for a CVD process, the polymer should be able to withstand temperatures of about 200° C. to about 300° C. Furthermore, the selection of one or more coating materials will depend on what reactants are used in the deposition process and which purge materials are employed to ensure that the coating material or materials will not react with the reactants or purge materials used in the respective deposition and purge processes.

In addition to TEFLON® coatings, other materials may be used to coat the exposed surfaces of the deposition chamber 10. Other coatings that may be used include, without limitation, various polymeric materials as well as metals. For instance, certain proprietary polymers available from General Magnaplate Corp., with corporate headquarters in Linden, N.J., may be used to coat exposed metallic surfaces in a deposition chamber 10. These polymers from General Magnaplate Corp. may be applied by first thoroughly cleaning the surface of the metal using metal cleaning processes well known by those of ordinary skill in the art (e.g., using a solvent, mechanical cleaning, flame cleaning, sand blasting, etc.), texturizing or etching the metal surface (e.g., mechanical etching such as sandblasting or rough grinding and chemical etching using acid-based etchants, etc) and, next, adhering Nickel (Ni) to the surface of the metal using well known metal deposition processes known by those of ordinary skill in the art (e.g., electroless or electrolytic plating processes). Once the Ni is adhered, pores in the Ni surface may be enlarged (e.g., using an acid solution to treat the metal surface) such that a polymer may be infused into the surface layer and bonded thereto. Suitable coating thicknesses may range from about 1 to about 2.5 mils.

Another polymer that may be adhered to the interior exposed surfaces of the deposition chamber 10 is a TUFRAM® brand coating, also available from General Magnaplate Corp., of Linden, N.J. TUFRAM® brand coating is described by the manufacturer as a synergistic coating. As used herein, the term “synergistic” will be used to refer to a coating that combines the advantages of anodizing, plating or thermal spraying with the controlled infusion of polymers, dry lubricants, or other materials that provide a composite coating with improved protection. The TUFRAM® brand coating may be adhered to an aluminum surface after converting the aluminum surface to Al₂O₃H₂O and replacing the H₂O with the TUFRAM® brand coating. The TUFRAM® brand coating may be applied to a thickness of about 0.0004 inches to about 0.003 inches, with a tolerance of ±0.0002 inches. Typical coating thicknesses of TUFRAM® brand coatings normally comprise 50% growth of the material above the surface of the metal and 50% penetration of the material into the metal surface. The coating locks within and over the crystal matrix to form a continuously sealed and lubricated surface with a hardness similar to that of case-hardened steel. Metal surfaces coated with TUFRAM® brand coatings may have hardness, wear and abrasion rates of about Rockwell C 65 and an equilibrium wear rate of about 0.5-1.5 mg per 1,000 cycles as measured using taper abrasion methods (e.g., CS17 wheel). Further, the TUFRAM®-coated metals may exceed MIL SPEC requirements by up to 30%. TUFRAM®-coated metals may also have coefficients of friction as low as 0.05, wherein the static coefficient of friction decreases with a load increase such that “stick-slip” is eliminated. However, the coefficients of friction may vary depending on the type of mating surfaces used. Further, TUFRAM® brand coated metals may be employed at intermittent operating temperatures between about −360° F. and about 800° F., depending on the process used to coat the metal and the type of metal alloy used. TUFRAM® brand coatings also usually exceed the basic 336 hour salt spray test requirement of MIL-A-8625 and may even exceed a 2,200 hour salt spray test. Additionally, some TUFRAM® brand coatings that may be used (i.e., R-66, 604, 611 and 615) are also resistant to most alkaline and acid solutions. One TUFRAM® brand coating currently believed to be suitable for use in the present invention is TUFRAM® 104 coating.

Yet another type of polymer that may be used to coat surfaces of metals such as aluminum and which is currently believed to be suitable for use in the present invention, is MAGNAPLATE HCR® brand coating available from General Magnaplate, Corp. of Linden, N.J. MAGNAPLATE HCR® brand coating is a synergistic coating that may be adhered to the metal at a thickness of about 0.001 inches to about 0.0025 inches with a tolerance of ±0.0002 inches. The growth of the MAGNAPLATE HCR® brand coating is also approximately 50% of the thickness value, the remainder being penetration. MAGNAPLATE HCR®-coated metals have hardness, wear and abrasion ratings of up to Rockwell C 65 and an equilibrium wear rate of about 1 mg per 1,000 cycles when measured using the taper abrasion testing method (CS-17 wheel). Metals coated with the MAGNAPLATE HCR® brand coatings may have coefficients of friction as low as 0.12 and an operating temperature range of about −200° F. to about 600° F. Corrosion resistance tests of MAGNAPLATE HCR®-coated metals using ASTM B-117 salt spray (5%) achieved on 6061-T6 may exceed 15,000 hours.

Other metallic coating materials, such as copper, nickel, cadmium, zinc, tin, or alloys thereof, may, for example, be placed on the interior surfaces of the deposition chamber 10 by electrolytic, immersion, or electroless plating. Metallic coating processes may passivate the surfaces by depositing a layer of metal on the surface, where the metal layer provides uniformity to the surface by depositing the metal in recesses, bores and blind holes in the surface and also provides a material less susceptible to contamination by precursor gases and vapors and resulting products. It will be appreciated that after the metallic coating is applied, an additional TEFLON® brand coating or other polymeric coating such as those offered by General Magnaplate, Corp. may be applied over the plated metal, as previously described herein, to fill the pores in and otherwise smooth the plated metal and provide a surface hostile to contamination.

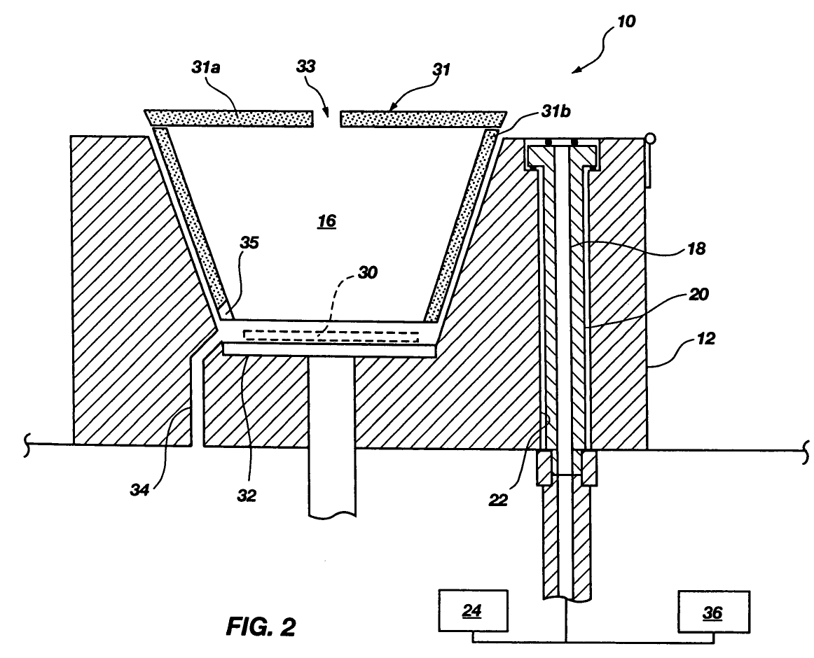

In another embodiment of the present invention, surfaces of a deposition chamber 10 may be lined, or covered, with a removable, nonreactive liner. Referring now to FIG. 2, there is shown a liner 31 being placed within the chamber cavity 16 of the deposition chamber 10. The location of a substrate 30 on which a thin film is to be formed when deposition chamber 10 is in operation is shown in broken lines for reference purposes. Deposition chamber 10 illustrated in FIG. 2 is substantially identical to the deposition chamber 10 of FIG. 1, with the exception that the chamber lid 14 has been removed. The liner 31 has openings 33 and 35 formed therein for the placement of the shower head 28 and the exhaust line 34, respectively, such that gases may enter and exit the chamber cavity 16 defined by the liner 31. As illustrated, the liner 31 is removable such that the liner 31 may be removed for cleaning or replacement when the liner 31 becomes contaminated. Also as illustrated, liner 31 may comprise a plurality of segments for ease of installation and access to chamber cavity 16. For example, and as illustrated, upper portion 31a linear 31 may be configured for attachment to chamber lid 14, while lower portion 31b of liner 31 may be formed as an open top and bottom, frustoconical structure with a notch or opening 35 at the lower end thereof to expose the inlet to exhaust line 34. Of course, any liner shape and number of liner portions to form a liner compatible with the shape of deposition chamber cavity 16 and inlets and outlets associated therewith may be employed. Examples of suitable materials that may be used for the liner include, but are not limited to, passivating metals, quartz, glass, ceramics, polymers, and other substantially chemically nonreactive (at least to purge and/or deposition processes to be used in a deposition chamber 10) materials known to those of ordinary skill in the art. The use of the liner 31 has the benefit that if the liner 31 is damaged, excessively worn, or becomes excessively contaminated with byproducts, it may simply be removed from the deposition chamber 10 and replaced. Thus, the user merely has to replace the liner 31 and not undertake cleaning or replacement of the entire deposition chamber 10. As illustrated, once the liner 31 is securely in place within the chamber cavity 16 of the deposition chamber 10, the lid 14 (with attached liner portion 31a, if desired) may be replaced (depicted in FIG. 1) for operation of the deposition chamber 10. It is contemplated that different portions of multi-portion liners may, of course, be fabricated from different materials, depending upon their intended placements.

In yet another embodiment of the invention, instead of coating or lining the surfaces of a deposition chamber 10 or in addition to coating or lining some of the interior surfaces of the deposition chamber 10, one or more of the various components of the deposition chamber 10 may be fabricated from a material which is substantially nonreactive to at least the deposition and purge processes to be used in the deposition chamber 10. For example, the shower head 28 and the substrate platform 32 may be fabricated out of quartz, such that reactant materials and purge materials are not adsorbed onto these components.

Furthermore, the reactant gas delivery path 18, the exhaust line 34, the shower head 28 and the substrate platform 32 may be fabricated such that they may be attached to the deposition chamber 10 in a manner to facilitate replacement if they become excessively contaminated with reactants or corroded thereby.

In yet another embodiment of the present invention, the exposed surfaces of a deposition chamber 10 may be chemically treated to passivate the same. The type of chemical treatment used to treat the surface may vary depending on the type of metal or other material used to construct the deposition chamber 10. For example, if aluminum is used to construct the deposition chamber 10, the surface of the aluminum may be passivated to produce a surface which is uniform, hard, and denser than the elemental aluminum or aluminum alloy surface. Passivating the surface of aluminum may be effected in any manner as previously disclosed herein.

Another exemplary chemical treatment that may be used to passivate an exposed surface of a deposition chamber 10 is known as “chromate conversion.” As known to those of ordinary skill in the art, chromate conversion is effected by treating the surface of the metal with chromic acid in the presence of a soluble salt. The resulting thin, gel-like film of metal oxide on the metal surface acts as a good adhesion layer for various materials and, in addition to its use as a passivating layer, may be used for subsequent adhesion of another (e.g., metal or polymer) passivation coating to the surface, as previously described herein. Metals including, but not limited to, aluminum, cadmium, copper, magnesium, silver, and zinc, may be passivated by chromate conversion.

If steel, other iron-containing metal alloys, or aluminum is used to construct the deposition chamber 10, the surface may be nitrided, wherein a hardened surface of nitride is produced by heating the metal surface in a nitrogen-containing material such that nitrogen diffuses into the surface and forms a hard case at the surface. The nitrided metal surface may then be additionally passivated by coating the same with a fluorinated polymer, such as a TEFLON® coating, another nonstick polymer coating, or a liner, as previously described herein.

The exposed metal surfaces may also be chemically passivated by exposing such surfaces to a passivating gas, such as nitrogen trifluoride, tungsten hexafluoride, or hydrogen bromide, or by flowing such a passivating gas along such surfaces as deposition or purge processes are being effected. Metal surfaces which may be passivated with gases include, but are not limited to, stainless steel, nickel, and HASTELLOY® brand nickel-based alloys available from Haynes International Inc., with headquarters in Kokomo, Ind. By way of example only, the passivating gas may react with a metal oxide on the surface of the metal and fluorinate or brominate the metal oxide to form an impervious fluoride or bromide layer, respectively, on the surface of the metal. The metal surface may be prepared for fluorination or bromination by electropolishing or chemically cleaning the surface in a manner well known to those of ordinary skill in the art. In the present invention, the passivating gas may be passed through the deposition chamber 10 as a step in the deposition process, or the passivating gas may be sent through the system after cleaning the deposition chamber 10, such that the impervious layer is formed prior to the start of a deposition process.

Instead of using a passivating gas, a gas plasma may also be used to passivate the metal surface. For example, argon, argon/helium, or argon/hydrogen may be passed through an electric arc to create a mixture of hot atoms, molecules, positive ions, and electrons and the mixture projected against the metal surface to passivate the metal surface. In the case of stainless steel, activated oxygen may be used as a passivation agent. Furthermore, powdered metal, oxides, carbides, or refractory materials (e.g., niobium, molybdenum, boron, silicon) may be introduced with the plasma in conjunction with an ion source to produce refractory material ions. The resulting refractory material ions may be projected against the metal surface to coat and passivate the surface. It will be appreciated that passivating the inside of the gas delivery path 18 or the exhaust line 34 may be difficult and there may be limitations on the length and width of a tube that may be passivated with plasma. Therefore, remote plasma processes may be used to passivate the interior of such conduits. Additionally, the species from which the plasma is generated may be sent through the conduit and subsequently activated within the conduit to passivate the interior of the conduit.

In a further embodiment of the present invention, the exposed metal surfaces within the deposition chamber 10 may be polished to a desired, measurable RMS value sufficient to reduce or eliminate reactant adhesion thereto using various techniques to substantially remove pits, ridges, voids, vugs and other surface roughness features from the metal surface to provide a homogenous surface. For instance, known electropolishing techniques may be used to polish at least some of the surfaces of the deposition chamber 10 to render them as smooth as possible. As known to those of ordinary skill in the art, electropolishing is accomplished by placing the metal in a chemical electrolyte bath and passing electrical current through the bath to remove metal ions from the surface of the metal to produce a smooth surface.

As an alternative to electropolishing, or in addition thereto, the metal surface may be polished using physical (e.g., flame, plasma, electrodischarge or laser), chemical, mechanical, or other methods of polishing known to those of ordinary skill in the art. Flame polishing may be accomplished on metal, glass, ceramic, or quartz surfaces used in the various embodiments of the present invention to close surface defects by localized application of heat. Flame polishing in the form of flame spraying may also be used on a metal surface wherein a wire, metal powder, or pellets are fed through a high temperature oxyacetylene torch gun, melted, and impinged on the metal surface in a semimolten state to provide a smooth, hard surface. Laser polishing uses a short laser pulse to melt and resolidify a surface layer to produce a resultant smooth layer. Chemical polishing techniques polish a metal surface using controlled chemical reactions, as known to those of ordinary skill in the art. For example, phosphoric acid, nitric acid, fluoride solutions, or combinations thereof may be used to dissolve the high points on a metallic surface and produce a smooth surface. Mechanical polishing may be accomplished using an abrasive material on a polishing pad, an abrasive slurry, or a buffer element, or by using a grit-blasting device.

The various methods of polishing metals described herein may be combined. For instance, large surface areas may be polished with mechanical polishing methods while areas not accessible to mechanical polishing may be polished using other methods (i.e., electropolishing the interior of tubing). Further, after a surface has been polished, the surface may be coated or otherwise treated, as described previously herein.

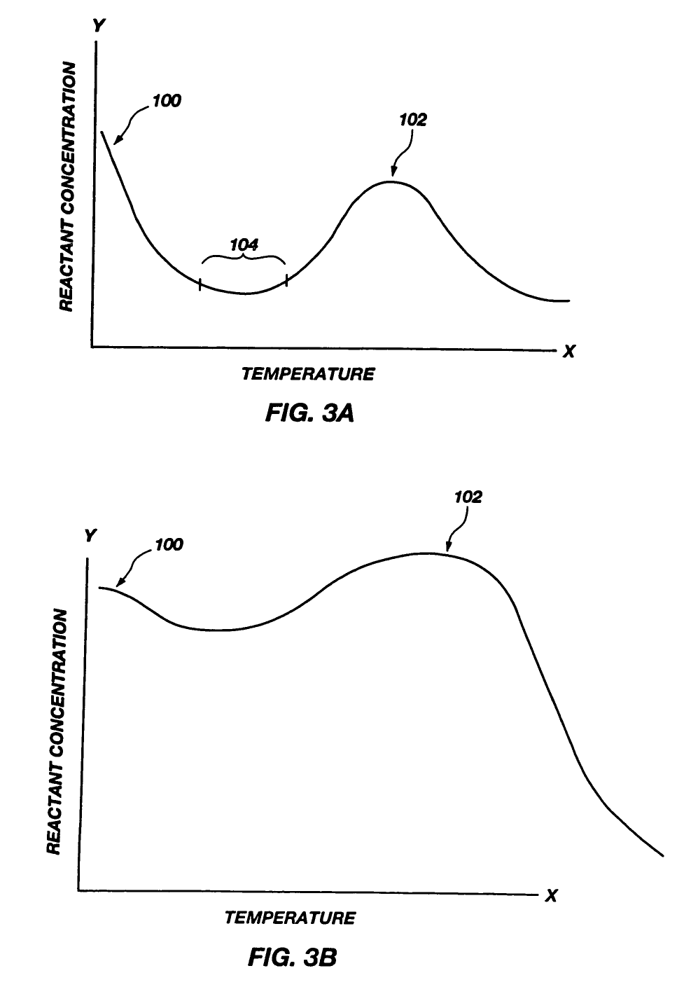

In a further embodiment of the present invention, the exposed surfaces of the deposition chamber 10 may be heated to or maintained at or within a particular temperature or temperature range to prevent the reactant gases from condensing on, physically adsorbing to, or chemically adsorbing to the surfaces. Referring now to FIG. 3A, there is shown a graph representing the physical adsorption and chemisorption of an exemplary reactant gas to a surface. On the graph, the X-axis represents an increasing temperature gradient of the surface, while the Y-axis represents an increasing concentration of the reactant gas adsorbing to the surface. As illustrated in FIG. 3A, a reactant typically physically adsorbs to the surface at lower temperatures, as indicated by a first peak 100 on the graph, while chemisorption typically occurs at higher temperatures, as shown by a second peak 102 on the graph. As known to those of ordinary skill in the art, the chemisorption peak is representative of the temperature at which deposition occurs during ALD processes. Therefore, deposition chamber surface temperatures associated with the chemisorption peak should be avoided to prevent the reactants from being chemisorbed onto the surfaces of the deposition chamber 10 (FIG. 1).

As further shown in the graph of FIG. 3A, there is exhibited a trough 104 through which temperature range the amount of reactant that adsorbs to a surface is minimized. This trough 104 lies between the physical adsorption peak 100 and the chemisorption peak 102 and represents an optimized temperature range to which the surfaces of the deposition chamber 10 may be heated in order to minimize reactant adsorption thereto. It will be appreciated that the peaks 100 and 102 and trough 104 will vary from reactant to reactant used in the deposition process, as well as for different deposition chamber 10 component materials. Therefore, a different optimized surface temperature profile may exist for each deposition reaction that will be used in a deposition chamber 10, as well as for each material used to fabricate various components of a deposition chamber 10. Once the optimized temperature or range for each surface material and the various reactants used in a particular deposition process are determined, the surface may be maintained at such temperature or within such range during the deposition phase to minimize adsorption of reactants or products to the surfaces of the deposition chamber 10.

However, it will be apparent to those of ordinary skill in the art that for some surfaces and reactants, the physical adsorption peak 100 may overlap, or partially overlap, with the chemisorption peak 102 or there may be no significant usable temperature or temperature range where reactant adsorption may be minimized, as shown in FIG. 3B. As illustrated in FIG. 3B, the temperature range at which a minimal amount of reactant adsorbs to the metal surface may occur at such a high temperature, that utilizing this embodiment of the invention may be undesirable for the particular surface and reactants that are to be used in a particular deposition process.

To determine an optimized temperature or temperature range at which to maintain surfaces in order to minimize physical adsorption of a reactant, the amount of reactant that physically adsorbs to the surface may be determined at varying temperatures. The amount of reactant that adheres to the surface by chemisorption at varying temperatures may also be determined. As depicted by the trough 104 in FIG. 3A, the temperature range at which a minimal amount of reactant adsorbs to the surface may include the temperature to which one or more surfaces of the deposition chamber 10 are heated and, thus, dynamically passivated.

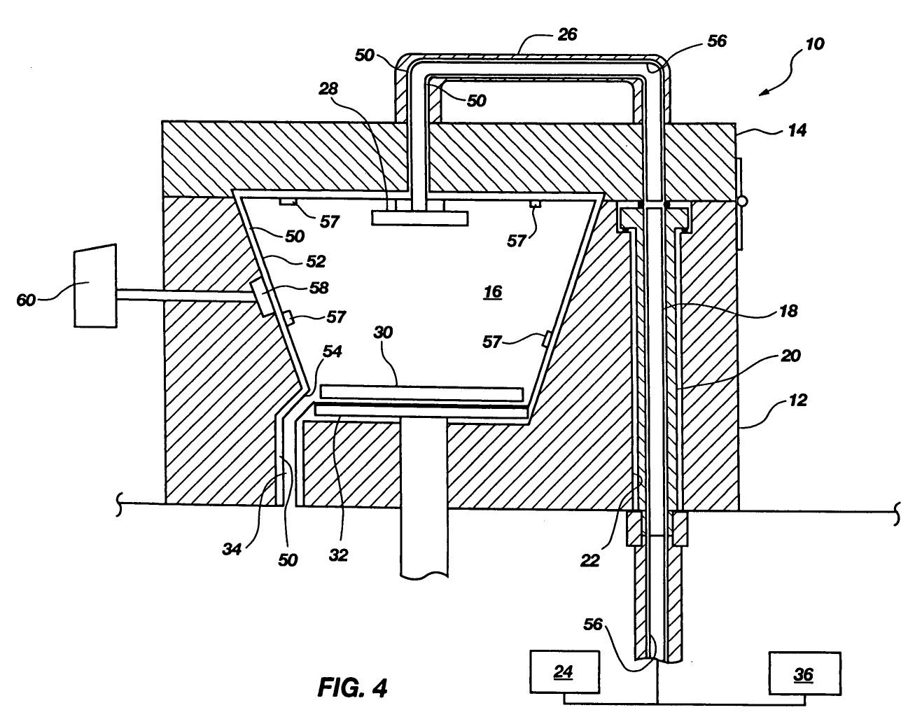

Referring now to FIG. 4, there is shown a deposition chamber 110 with one or more heating elements 50 used to heat the various surfaces therewithin or associated therewith, either collectively or individually (e.g., when it is desirable to heat different surfaces of the deposition chamber 110 to different temperatures). Heating elements 50 may comprise, for example, electrical resistance-type heating elements which are easy to configure to various component and surface shapes. The deposition chamber 110 of FIG. 4 may be substantially the same in construction as the deposition chamber 10 described herein with reference to FIG. 1. However, the deposition chamber 110 of FIG. 4 includes the added feature of one or more heating elements 50. As depicted, the heating element 50 may substantially surround all interior surfaces of the deposition chamber 110 where the reactant and purge gases contact the deposition chamber 110 during the deposition process. The heating element(s) 50 may be used to heat interior exposed surfaces 52 within the chamber cavity 16, interior exposed surfaces 54 within the exhaust line 34 and exposed interior surfaces 56 within the gas delivery path 18, and the gas delivery head 28. Heating the interior exposed surfaces 52, 54 and 56 to the ideal temperature(s) minimizes physical adsorption and chemisorption of reactants or reaction products thereto, as represented by the trough 104 previously described herein with reference to FIG. 3A, thereby passivating the interior surfaces 52, 54 and 56.

The deposition chamber 110 of FIG. 4 may also include one or more temperature sensors 57, such as thermocouples or chip-based temperature sensors of known types, such that the temperature at one or more locations on the interior surface 52 of the deposition chamber 110 may be monitored and, thus, more efficiently controlled by way of a feedback system 60 (e.g., a processor or smaller group of logic circuits) which communicates with each temperature sensor 57 to receive signals indicative of the temperature of a respective interior surface 52, 54 or 56 and provide, remove or regulate power to each heating element 50 to control the temperature output thereof.

Heat exchangers 58 may also be employed in conjunction with, or in lieu of, heating elements 50 to regulate exposed interior surface temperatures of deposition chamber 110, surface temperatures again being regulated by a feedback system 60 responsive to outputs of one or more temperature sensors 57. Accordingly, and dependent upon the process involved and temperature range thereof, it is contemplated that deposition chamber component surfaces may be cooled as well as heated to maintain an optimized surface temperature condition to defeat deposition of precursor materials and consequent formation of particlulate contaminants. Conventional, fluid-filled heat exhanger circuits may be used to regulate temperature, or compact and reversible thermoelectric heat exchangers may be employed, the type of heat exchanger selected being immaterial to implementation of the present invention. One heat exchanger 58 is illustrated, but any number of heat exchangers 58 may be used without departing from the spirit of the present invention. Although the temperature sensors 57 are illustrated as disposed on the interior surface 52 of the deposition chamber 110 for clarity and simplicity, the temperature sensors 57 may also be located under the interior surface 52 or under or collocated with the heating elements 50. In addition to passivating the interior surfaces 52 of the deposition chamber 110 using heating elements 50 or heat exchangers 58, the interior surfaces 52 of the deposition chamber 110 may also be chemically treated, polished, or coated as previously described herein.

The various embodiments described herein may be combined in any number of ways to passivate the surfaces of the deposition chamber 10. For example, surfaces of the deposition chamber 110 employing the heating element 50 may also be polished, chemically treated, and coated as previously described herein to minimize incidental deposition as much as possible.

Although the present invention has been shown and described with respect to various illustrated embodiments, various additions, deletions and modifications that are obvious to a person of ordinary skill in the art to which the invention pertains, even if not shown or specifically described herein, are deemed to lie within the scope of the invention as encompassed by the following claims.

What is claimed is:

1. A method of passivating surfaces in an apparatus for depositing a film of at least one material on at least one substrate, comprising:
providing an apparatus including a deposition chamber configured to receive at least one substrate therein and a plurality of conduits in communication therewith, the deposition chamber and the plurality of conduits comprising an interior surface exposed to at least one reactant gas or vapor when the deposition chamber is operative to deposit the film of the at least one material on the at least one substrate; and
treating at least a portion of the interior surface to render the at least a portion resistant to accumulation of at least one reactant gas or vapor used in depositing the film of the at least one material on the at least one substrate.

2. The method according to claim 1, wherein treating comprises applying a layer of at least one material to the at least a portion of the interior surface.

3. The method according to claim 2, wherein applying comprises:
roughening the at least a portion of the interior surface;
applying a primer to the at least a portion of the interior surface; and
embedding a fluorinated polymer to the at least a portion of the interior surface.

4. The method according to claim 2, wherein applying comprises:
cleaning the at least a portion of the interior surface;
etching the at least a portion of the interior surface;
disposing nickel on the at least a portion of the interior surface;
enlarging pores in the nickel; and
bonding a polymer to the at least a portion of the interior surface by introducing the polymer into the enlarged pores.

5. The method according to claim 2, wherein applying comprises applying a synergistic coating to the at least a portion of the interior surface.

6. The method according to claim 5, wherein applying a synergistic coating to the at least a portion of the interior surface comprises applying one of a TUFRAM® coating and a MAGNAPLATE HCR® coating.

7. The method according to claim 2, wherein applying comprises disposing a liner over the at least a portion of the interior surface.

8. The method according to claim 7, wherein disposing the liner comprises disposing a liner including a plurality of portions.

9. The method according to claim 7, further comprising selecting the liner from at least one of glass, quartz, ceramic, and metal.

10. The method according to claim 1, wherein treating comprises polishing the interior surface.

11. The method according to claim 10, wherein polishing comprises at least one of electropolishing, mechanical polishing, chemical polishing, electrodischarge polishing, laser polishing and flame polishing.

12. The method according to claim 1, wherein treating comprises at least one of chemical passivation and plasma passivation.

13. The method according to claim 1, wherein treating comprises forming a metal oxide layer on the at least a portion of the interior surface.

14. The method according to claim 1, wherein treating comprises treating the at least a portion of the interior surface with chromic acid in a soluble salt.

15. The method according to claim 1, wherein treating comprises nitriding the at least a portion of the interior surface.

16. The method according to claim 1, further comprising:
forming a fluorine-containing layer or a bromine-containing layer on at least a portion of the interior surface.

17. A method for dynamically passivating at least one interior surface in an apparatus for depositing a film of at least one material on at least one substrate, comprising:
providing an apparatus including a deposition chamber and a plurality of conduits in communication therewith, the deposition chamber and the plurality of conduits comprising an interior surface exposed to at least one reactant gas or vapor when the deposition chamber is operative to deposit the film of the at least one material on the at least one substrate; and
maintaining at least a portion of the interior surface within at least a predetermined temperature range during a deposition operation to render the at least a portion of the interior surface resistant to accumulation of the at least one reactant gas or vapor thereon.

18. The method according to claim 17, further comprising monitoring a temperature of the at least a portion of the interior surface.

19. The method according to claim 18, further comprising at least one of adding heat to the at least a portion of the interior surface or removing heat therefrom responsive to the monitoring.

20. A method for minimizing an amount of at least one reactant gas or vapor that accumulates on at least a portion of an interior surface of an apparatus for depositing a film of at least one material on at least one substrate, comprising:
measuring an amount of at least one reactant gas or vapor that physically adsorbs to a material proposed for use on the at least a portion of the interior surface at each of a plurality of temperatures over at least a portion of a temperature range;
measuring an amount of the at least one reactant or a reaction product that chemisorbs to the material proposed for use on the at least a portion of the interior surface at each of a plurality of temperatures over at least a portion of the temperature range; and
determining if there is at least one temperature within the temperature range at which an accumulation of the at least one reactant gas or vapor on the material is minimized due to a combination of physical adsorption and chemisorption.

21. The method according to claim 20, further comprising determining if there is at least another temperature within the temperature range within which the accumulation of the at least one reactant gas or vapor is minimized due to a combination of physical adsorption and chemisorption.

22. The method according to claim 21, further comprising operating the apparatus to deposit the film of at least one material on at least one substrate using the at least one reactant gas or vapor, the apparatus having the at least a portion of the interior surface thereof formed of the material, while maintaining the at least a portion of the interior surface at substantially at the at least another temperature.

23. The method according to claim 20, further comprising operating the apparatus to deposit the film of at least one material on the at least one substrate using the at least one reactant gas or vapor, the apparatus having the at least a portion of the interior surface thereof formed of the material, while maintaining the at least a portion of the interior surface at substantially the at least one temperature.
